(19) United States
(12) Patent Application Publication
(10) Pub. No.: US 2018/0342640 A1
(43) Pub. Date: Nov. 29, 2018

(54) COLORED PHOTOVOLTAIC MODULE WITH NANOPARTICLE LAYER

(71) Applicant: TESLA, INC., Palo Alto, CA (US)

(72) Inventors: Yangsen Kang, Santa Clara, CA (US); Nathan D. Rock, Salt Lake City, UT (US); Jiunn Benjamin Heng, Los Altos Hills, CA (US)

(73) Assignee: TESLA, INC., Palo Alto, CA (US)

(21) Appl. No.: 15/821,274

(22) Filed: Nov. 22, 2017

Related U.S. Application Data
(60) Provisional application No. 62/510,644, filed on May 24, 2017.

(51) Int. Cl. H01L 31/054; H01L 31/049; H01L 31/18

(52) U.S. Cl. CPC H01L 31/0547; H01L 31/18; H01L 31/049

(57) ABSTRACT

A colored photovoltaic (PV) module or roof tile including a layer of highly stable nanoparticles provides uniform, angle-independent viewer color. The nanoparticles can comprise a metal oxide such as zinc oxide, titanium dioxide, or iron oxide. The nanoparticles can have composition and/or size tuned to absorb wavelengths of light reflected from PV cells, effectively concealing their appearance, and tuned to scatter wavelengths in a desired color range. The disclosed embodiments can provide better color uniformity and better efficiency, and be more cost-effective, than existing approaches for manufacturing colored PV modules. During the manufacturing process, a coating system, which may include one or more nozzles, can spray an inside surface of a glass cover with nanoparticles, which can be suspended in a solvent (such as water or isopropyl alcohol). The nanoparticle layer can then be encapsulated directly inside an encapsulant layer.

### RELATED APPLICATION

This application claims the benefit of U.S. Provisional Application No. 62/510,644, Attorney Docket Number P377-1PUS, entitled “COLORED PHOTOVOLTAIC ROOF TILES AND METHOD FOR MANUFACTURING THEREOF,” by inventors Yangsen Kang, Nathan D. Rock, and Jiunn Benjamin Heng, filed 24 May 2017.

### BACKGROUND

### Field

This disclosure is generally related to colored photovoltaic (or “PV”) modules or roof tiles. More specifically, this disclosure is related to PV modules including a layer of nanoparticles to provide a uniform color.

### Related Art

A typical photovoltaic (PV) panel or module can include a two-dimensional array (e.g., 6×12) of solar cells. A PV roof tile (or solar roof tile) can be a particular type of PV module shaped like a roof tile and enclosing fewer solar cells than a conventional solar panel, and can include one or more solar cells encapsulated between a front cover and a back cover. These covers can be glass or other material that can protect the solar cells from the weather elements. The array of solar cells can be sealed with an encapsulating layer, such as an organic polymer, between the front and back covers.

Conventionally, the color of a PV module or solar roof tile corresponds to the natural color of the solar cells, which can be blue, dark-blue, or black. A number of techniques are available to improve the color appearance of a PV module so that, for example, the module matches the color of a building, or the module's appearance can conceal the solar cells.

One such color-management technique involves depositing an optical filter, such as a layer of transparent conductive oxide (TCO), within the PV module, e.g., on the inner surface of a front glass cover that encapsulates the solar cells. The optical coating can be deposited using, for example, a physical vapor deposition (PVD) technique. Although PVD-based optical coating can use thin-film interference effects to achieve the desired color effect on photovoltaic roof tiles, such coatings can suffer from flop, or angle-dependent color appearance (i.e. an angular dependence of the reflected wavelength). In addition, the PVD process can be expensive for high-volume manufacturing.

### SUMMARY

One embodiment described herein provides a photovoltaic module. This photovoltaic module comprises a front glass cover, wherein an inner surface of the front glass cover is coated with a layer of material that contains nanoparticles, which facilitates reflection of light of a predetermined color. Moreover, the photovoltaic module comprises a back cover and at least one solar cell positioned between the front glass cover and the back cover.

In a variation on this embodiment, the nanoparticles comprise at least one of: ZnO, TiO₂, Fe₂O₃, and Fe₃O₄.

In a variation on this embodiment, a diameter of the nanoparticles has a range of 10-1000 nm.

In a variation on this embodiment, the nanoparticles are suspended in an encapsulant material.

In a variation on this embodiment, the encapsulant material comprises thermoplastic polyolefin (TPO) or ethylene-vinyl acetate (EVA).

In a variation on this embodiment, the nanoparticles comprise a ceramic.

In a variation on this embodiment, the layer of material contains two types of nanoparticles having different compositions and/or sizes.

In a variation on this embodiment, the nanoparticles are sprayed in a liquid or emulsion onto an inner surface of the glass cover.

In a variation on this embodiment, the liquid or emulsion comprises water, isopropyl alcohol (IPA), and 0.1% to 20% nanoparticles by weight or volume.

Another embodiment described herein provides a method for manufacturing a photovoltaic module. The method comprises spraying a layer of liquid or emulsion that contains nanoparticles onto an inner surface of a front glass cover. The method then comprises encapsulating at least one solar cell between the front glass cover and a back cover, wherein the nanoparticles are positioned between the front glass cover and the solar cell, thereby allowing the nanoparticles to reflect light of a predetermined color.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1 shows an exemplary configuration of photovoltaic roof tiles on a house.

FIG. 2 shows a perspective view of the configuration of a photovoltaic roof tile, according to an embodiment.

FIG. 3A shows a cross section of an exemplary photovoltaic module or roof tile.

FIG. 3B shows the cross section of an exemplary photovoltaic module or roof tile including a layer of nanoparticles, according to an embodiment.

FIG. 4A illustrates measured spectra of selective scattering of light by nanoparticles of various iron oxide compositions.

FIG. 4B illustrates measured reflectance spectra of metal oxide nanoparticles of various sizes and compositions.

FIG. 4C illustrates measured absorption spectra of metal oxide nanoparticles of various sizes and compositions.

FIG. 4D illustrates measured reflectance spectra for a mixture of iron oxide and titanium oxide nanoparticles.

FIG. 5A illustrates coating of a glass cover sheet with a layer of nanoparticles, according to an embodiment.

FIG. 5B illustrates spray nozzles used to coat a glass cover sheet with a layer of nanoparticles, according to an embodiment.

FIG. 6 illustrates an exemplary as-deposited photovoltaic module or roof tile containing a layer of nanoparticles, according to an embodiment.

FIG. 7 shows a block diagram illustrating a process for depositing a layer of nanoparticles in a photovoltaic module or roof tile, according to an embodiment.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the disclosed system is not limited to the embodiments shown, but is to be accorded the widest scope consistent with the principles and features disclosed herein.

### Overview

Embodiments described herein solve the problem of providing uniform, angle-independent color in a photovoltaic (PV) module or roof tile, and concealing the appearance of PV cells, by including a layer of highly stable nanoparticles (NPs). The nanoparticles can include a metal oxide such as zinc oxide, titanium dioxide, or iron oxide. The nanoparticles can have composition and/or size tuned to absorb substantially the same wavelengths of light reflected from PV cells, thereby effectively concealing the PV cells' appearance. The nanoparticles' properties can also be tuned to scatter wavelengths in a range corresponding to a desired color appearance, which can reduce PV cell and module color contrast or angle-dependence of color. The disclosed embodiments can provide better color uniformity and better efficiency, and be more cost-effective, than existing approaches for manufacturing colored PV modules.

During the manufacturing process, a coating system, which may include one or more nozzles, can spray the inside surface of a glass cover with a suspension or emulsion of nanoparticles. The nanoparticles can be suspended in a medium (such as water or isopropyl alcohol). The nanoparticle layer can then be encapsulated by an encapsulant layer.

A layer of nanoparticles as disclosed herein has reliability advantages over existing color-management systems for PV modules, including good pull-force (adhesion) performance and current-leakage characteristics. To optimize reliability and extend useful life of the PV module or roof tile, the nanoparticles preferably comprise materials having thermal, chemical, and electrical stability. For example, the nanoparticles can include materials with low electrical conductivity, such as insulators or wide-bandgap semiconductors, to avoid current leakage when the PV roof tile is wet. Materials maintaining a stable phase (i.e., solid) at the operating temperatures are also preferable to avoid reliability issues.

In one embodiment, the nanoparticles can include a non-conductive metal oxide including one or more of: zinc oxide (ZnO); titanium dioxide (TiO₂); and iron oxide, such as iron(III) oxide (Fe₂O₃), and iron(II,III) oxide (Fe₃O₄). In another embodiment, the nanoparticles can include a ceramic material. Note that the nanoparticles can be based on any stable materials, and are not limited by the present disclosure. For example, the layer of nanoparticles can include a mixture of two or more types of nanoparticles having different compositions, sizes, and/or optical properties.

Additional reliability can be attained when the nanoparticles dissolve into the encapsulant material, e.g., thermoplastic polyolefin (TPO) or ethylene-vinyl acetate (EVA), during the lamination process. Thus, curing or treatment processes can be optional for the nanoparticles, and the final roof tile product can withstand a large amount of pull force due to good adhesion between encapsulant layers. Also, because the nanoparticles are encapsulated, these particles are not exposed to the atmosphere, and therefore are protected from corrosion.

Furthermore, the disclosed embodiments have significant manufacturing and cost advantages over existing systems, such as the PVD process for coating an optical filter layer on the PV module's glass cover. Whereas PVD requires a vacuum chamber, a nanoparticle layer can be coated on the glass with only an in-air multi-nozzle-spray system. In addition, the material cost of the nanoparticles can be less expensive than the optical filter layer.

### PV Roof Tiles and Modules

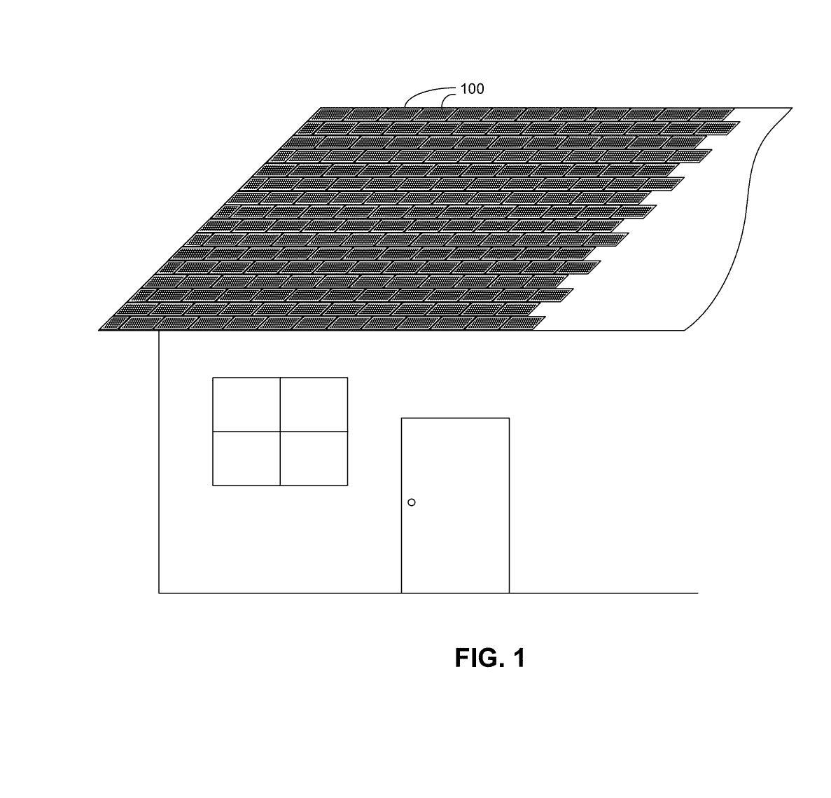

The disclosed system and methods may be used to provide more uniform color and conceal PV cells' appearance in PV roof tiles and/or PV modules. Note that such PV roof tiles can function as solar cells and roof tiles at the same time. FIG. 1 shows an exemplary configuration of PV roof tiles on a house. PV roof tiles 100 can be installed on a house like conventional roof tiles or shingles. Particularly, the PV roof tiles can be placed in such a way to prevent water from entering the building.

Within a PV roof tile, a respective solar cell can include one or more electrodes such as busbars and finger lines, and can couple electrically to other cells. Solar cells can be electrically coupled by a tab, via their respective busbars, to create in-series or parallel connections. Moreover, electrical connections can be made between two adjacent tiles, so that a number of PV roof tiles can jointly provide electrical power.

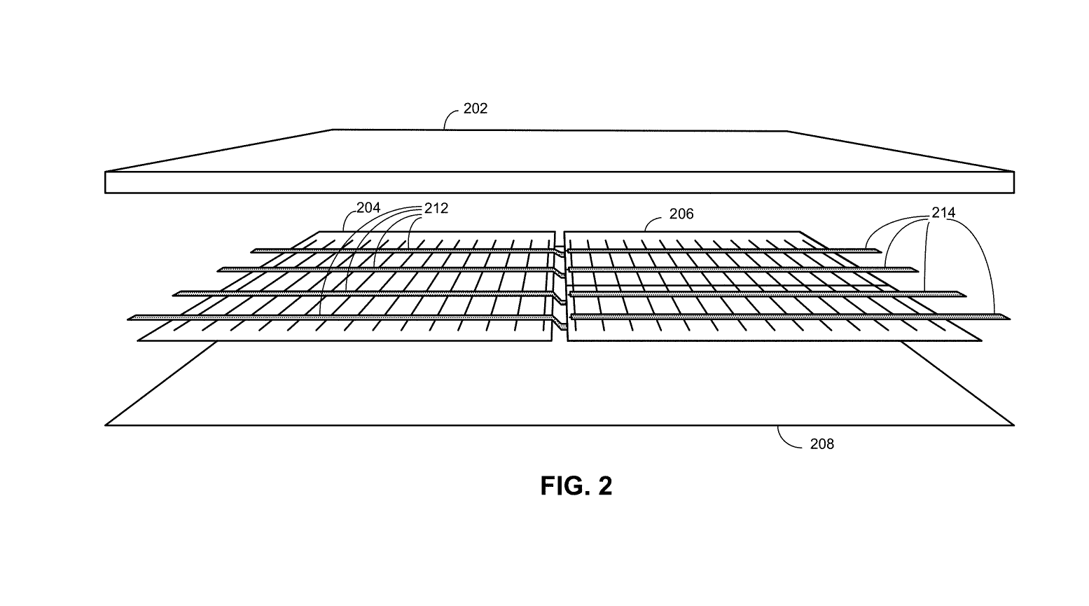

FIG. 2 shows a perspective view of the configuration of a photovoltaic roof tile, according to an embodiment. In this view, solar cells 204 and 206 can be hermetically sealed between top glass cover 202 and backsheet or back glass cover 208, which jointly can protect the solar cells from the weather elements. Tabbing strips 212 can be in contact with the front-side electrodes of solar cell 204 and extend beyond the left edge of glass cover 202, thereby serving as contact electrodes of a first polarity of the PV roof tile. Tabbing strips 212 can also be in contact with the back side of solar cell 206, creating an in-series connection between solar cell 204 and solar cell 206. Tabbing strips 214 can be in contact with front-side electrodes of solar cell 216 and extend beyond the right-side edge of glass cover 202.

Using long tabbing strips that can cover a substantial portion of a front-side electrode can ensure sufficient electrical contact, thereby reducing the likelihood of detachment. Furthermore, the four tabbing strips being sealed between the glass cover and backsheet can improve the durability of the PV roof tile.

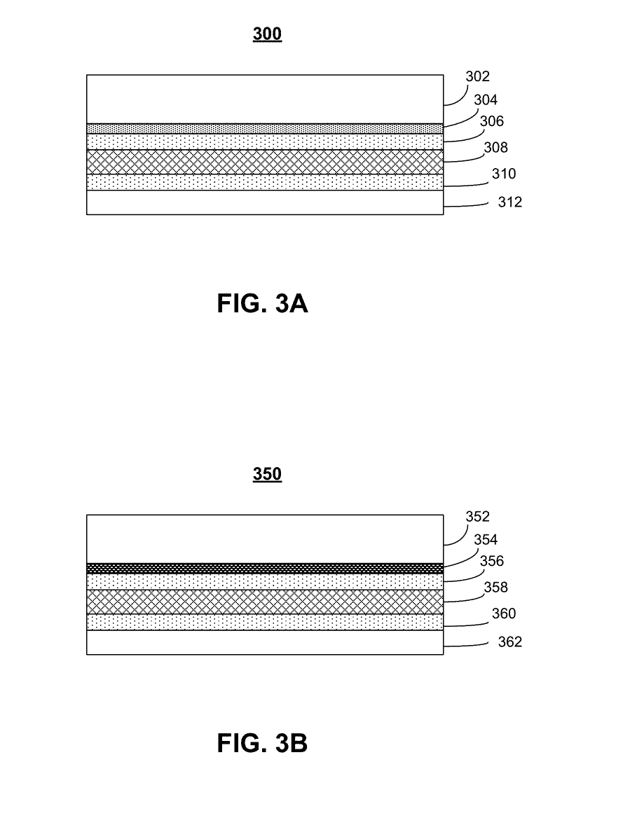

FIG. 3A shows a cross section of an exemplary photovoltaic module or roof tile 300. In this example, solar cell or array of solar cells 308 can be encapsulated by top glass cover 302 and backsheet or back glass cover 312. Top encapsulant layer 306, which can be based on a polymer, can be used to seal between top glass cover 302 and solar cell or array of solar cells 308. Specifically, encapsulant layer 306 may include polyvinyl butyral (PVB), thermoplastic polyolefin (TPO), ethylene vinyl acetate (EVA), or N,N′-diphenyl-N,N′-bis(3-methylphenyl)-1,1′-diphenyl-4,4′-diamine (TPD). Similarly, back encapsulant layer 310, which can be based on a similar material, can be used to seal between array of solar cells 308 and backsheet or glass cover 312. PV roof tiles and modules are described in more detail in U.S. Provisional Patent Application No. 62/465,694, Attorney Docket Number P357-1PUS, entitled “SYSTEM AND METHOD FOR PACKAGING PHOTOVOLTAIC ROOF TILES” filed Mar. 1, 2017, which is incorporated herein by reference. The embodiments disclosed herein can be applied to solar cells, PV roof tiles, and/or PV modules.

One existing technique for providing color to a PV roof tile or module involves depositing an optical filter within the PV module via a process such as PVD. In the example of FIG. 3A, module or roof tile 300 can also contain an optical filter layer 304 (also referred to as optical coating or color filter layer) comprising one or more layers of optical coating, which provide color via thin film interference effects. Optical filter layer 304 can contain a transparent conductive oxide (TCO) such as Iridium Tin Oxide (ITO) or Aluminum-doped Zinc Oxide (AZO), or a multi-layer stack containing materials of different refractive indices. PV roof tiles and modules using a color filter layer are described in more detail in U.S. patent application Ser. No. 15/294,042, Attorney Docket Number P301-2NUS, entitled “COLORED PHOTOVOLTAIC MODULES” filed Oct. 14, 2016, which is incorporated herein by reference.

However, optical filter layers based on thin film interference may suffer from contrast between the PV cell and PV module, or angle-dependent color appearance, which can compromise the aesthetic appearance. The system and methods disclosed herein provide an alternative source of color in PV modules, i.e., scattering of specific wavelengths of light by a layer of nanoparticles. Nanoparticles offer several advantages over a PVD-deposited color filter layer, including better color uniformity, energy efficiency, cost-effectiveness, and reliability.

FIG. 3B shows the cross section of an exemplary photovoltaic module or roof tile 350 including a layer of nanoparticles, according to an embodiment. Module or roof tile 350 has a similar structure to module or roof tile 300 shown in FIG. 3A, including solar cell or array of solar cells 358 encapsulated by top glass cover 352 and backsheet or back glass cover 362. Top encapsulant layer 356 seals between top glass cover 352 and solar cell or array of solar cells 358. Back encapsulant layer 360 can seal between array of solar cells 358 and backsheet or back glass cover 362.

PV module or roof tile 350 contains nanoparticle layer 354. In one embodiment, nanoparticle layer 354 can absorb or filter out light in a wavelength range corresponding to the light reflected by solar cells 358 (typically blue), thus hiding the solar cells' appearance from a viewer. Nanoparticle layer 354 can also scatter or reflect light of wavelengths corresponding to a desired color appearance (e.g., red light), thus providing a substantially uniform color (e.g., terracotta, grey, or black).

Uniform Color Appearance Based on Mie Scattering from Nanoparticles

The disclosed system and methods can provide uniform, angle-independent color in a PV module or roof tile by reflecting, scattering, and/or absorbing light by a layer of nanoparticles. Specifically, the nanoparticle layer can effectively conceal the appearance of PV cells by absorbing a wavelength range corresponding to the color (typically blue or dark blue) of the PV cells. Consequently, the nanoparticle layer can filter out light reflected by the PV cells, preventing it from reaching a viewer's eye. At the same time, scattering from the nanoparticle layer with its scattering peak in a particular wavelength range can provide a uniform color appearance. Because this colored light is scattered (and the nanoparticles are randomly and isotropically distributed in the layer), the light displays little contrast between the PV cell and module and little “flop,” or angle-dependence of color.

With the disclosed system and methods, it is possible to precisely tune the nanoparticle layer to filter some wavelengths and scatter others, e.g. by adjusting nanoparticle properties such as size and composition. Both the nanoparticle's size (e.g., measured by diameter) and material can affect the nanoparticle's bandgap, absorption, and scattering. By contrast, in PVD-deposited optical filter films, color is determined by refraction and interference of reflected light waves from the thin film's surfaces. Thus PVD-deposited films may lack fine-grained adjustment of absorption and scattering spectral features comparable with the disclosed nanoparticle layer.

The nanoparticle's size can determine its scattering profile and the location of its scattering peaks, and consequently the nanoparticle layer's color appearance. The case of scattering from nanoparticles with diameter much less than visible wavelengths is well described by Rayleigh scattering. Such particles experience only minimal scattering of visible light, and therefore have a visible color dominated by scattering in the blue or violet ranges. Mie or selective scattering refers to the more general case, and especially the case of particles with diameters comparable to visible wavelengths (i.e., hundreds of nanometers). These nanoparticles experience strong selective scattering of light with a similar wavelength.

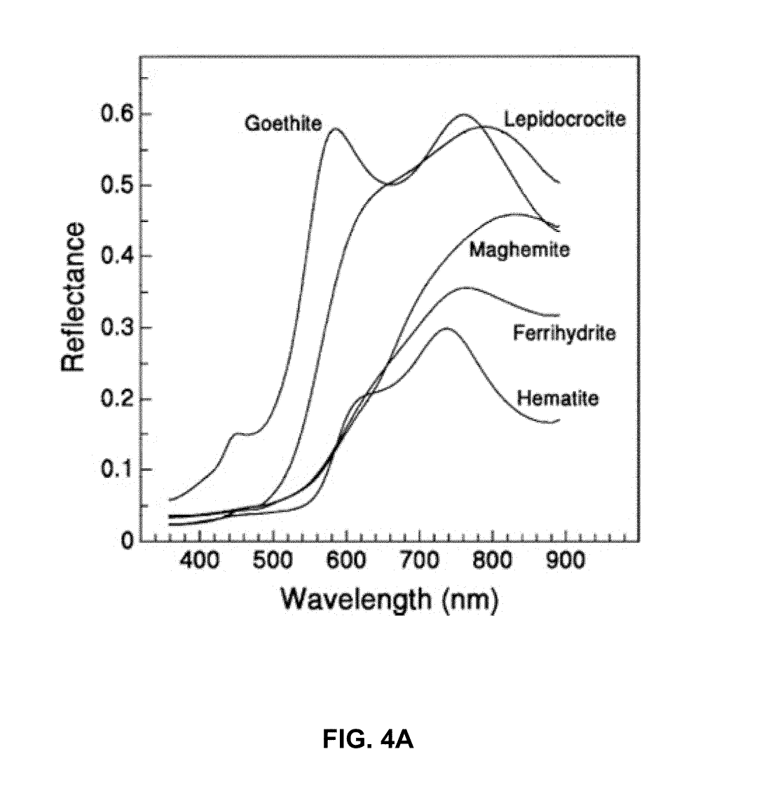

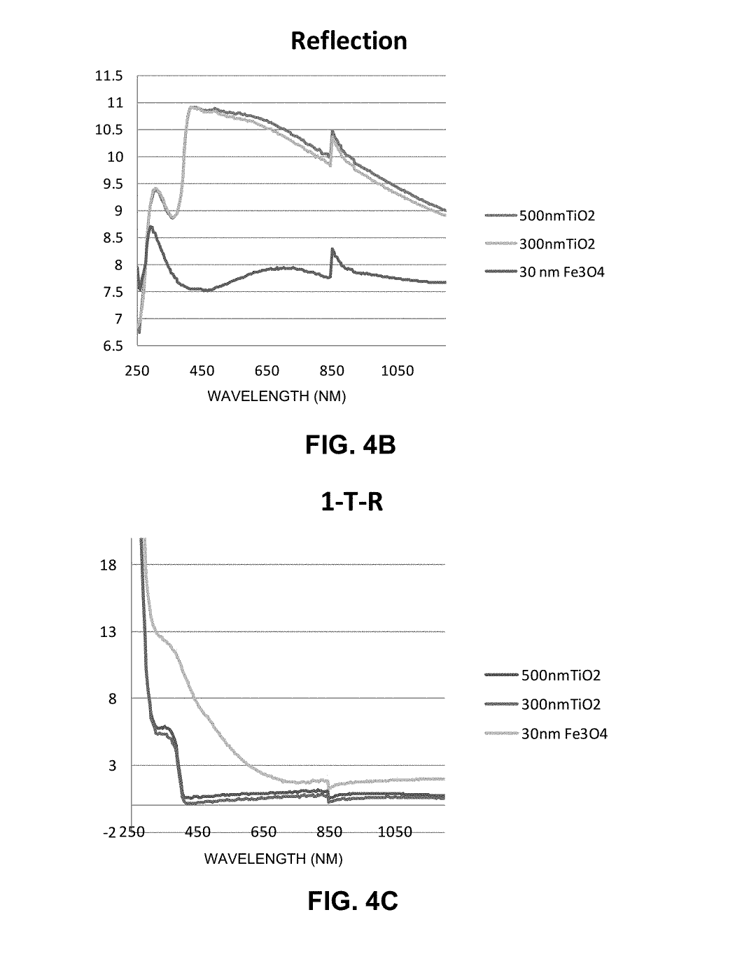

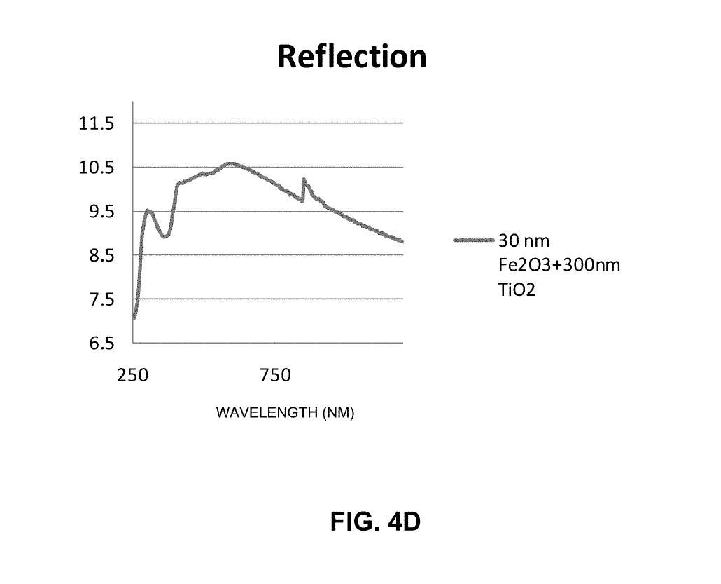

While the nanoparticle's size is important in determining its scattering spectrum, its composition can also affect the spectrum. FIG. 4A illustrates measured spectra of selective scattering of light by nanoparticles of various iron oxide compositions. As shown, the number, location, and breadth of scattering peaks vary among different iron oxides. Iron oxide scattering peaks, as shown in FIG. 4A, are generally in the red and infrared ranges.

Note that the nanoparticles can help scatter red light for PV modules with a desired red hue. For example, Fe₂O₃ nanoparticles can be used to absorb blue light from the PV cells and reflect other colors of light. In some embodiments, TiO₂ nanoparticles can be used to scatter red light, including light reflected from Fe₂O₃, for a red appearance (e.g., terracotta).

FIG. 4B illustrates measured reflectance spectra of metal oxide nanoparticles of various sizes and compositions. As shown, for TiO₂ nanoparticles, scattering has peaks around blue (450 nm) and red-infrared (850 nm) wavelengths. Moreover, particle size is seen to affect the scattering spectrum, with the magnitude of scattering suppressed for the smaller 300 nm particles compared with the 500 nm particles, especially for wavelengths longer than 300 nm. For 30 nm Fe₃O₄ nanoparticles, scattering is further suppressed, but the spectrum displays peaks around 300 nm and 850 nm.

In addition to controlled scattering, the nanoparticle bandgap, size, and composition can also be engineered to achieve controlled absorption. For example, for Fe₃O₄ nanoparticles, the bandgap increases with decreasing particle size, which in turn affects the particles' absorption spectrum. This increased bandgap can produce absorption peaks at specific wavelengths, and therefore the nanoparticle layer can be used to filter out these wavelengths.

FIG. 4C illustrates measured absorption spectra of metal oxide nanoparticles of various sizes and compositions. As shown, 300 nm and 500 nm TiO₂ nanoparticles have similar absorption, with absorption for the larger TiO₂ particles slightly stronger for wavelengths longer than 300 nm. Meanwhile, 30 nm Fe₃O₄ nanoparticles display significantly stronger absorption, especially for wavelengths shorter than 650 nm. As absorption helps reduce back-reflection from the PV cells, the system may preferably use 30 nm nanoparticles such as Fe₃O₄ or Fe₂O₃ to absorb back-reflected blue light.

In some embodiments, the nanoparticle layer can include a mixture of two or more types of nanoparticles with different compositions or sizes, in order to tune both absorption and scattering properties simultaneously. That is, the layer may contain one type of nanoparticles tuned to absorb blue light, and a second type of nanoparticle tuned to scatter a desired color of the PV tile. For example, the layer could contain 30 nm iron oxide nanoparticles (such as Fe₃O₄ or Fe₂O₃) as described above to absorb light from the PV cells, together with titanium dioxide (TiO₂) to provide a red hue.

FIG. 4D illustrates measured reflectance spectra for a mixture of iron oxide and titanium oxide nanoparticles. As shown, this combination has a reflectance spectrum that largely resembles that of TiO₂ for wavelengths greater than 700 nm (corresponding to red and infrared) and those below 300 nm (corresponding to ultraviolet). However, for intermediate wavelengths between approximately 400 nm and 500 nm (corresponding to blue and violet light), the presence of Fe₂O₃ causes strong absorption, significantly lowering total reflectance.

In some embodiments, the layer may also contain more than two types of nanoparticles (for example, to scatter a mixture of two colors, or to provide more efficient absorption). Thus, tuning a layer of nanoparticles for both absorption and scattering allows precision control over what colors reach a viewer's eye.

### Advantages of Nanoparticle Layer

As described above, the nanoparticle layer can provide precise control over the color appearance of the PV module. Further advantages of the nanoparticle layer include improved color uniformity, energy efficiency, cost-effectiveness, reliability, and high-volume manufacturing (HVM) scalability compared with existing systems.

Table 1 compares both color match and current loss of nanoparticle-coated tiles and PVD coated tiles, according to an embodiment. As shown in Table 1, good color matching has been demonstrated. The PVD black and grey samples show a L*a*b* color difference ΔE*=\sqrt{(ΔL*²+Δa*²+Δb*²)} (where L* is lightness and a* and b* are color opponents green-red and blue-yellow) of 4.2 and 2.8, respectively, whereas the nanoparticles have ΔE* ranging from 2.8 to 3.8.

With regard to efficiency, or the loss of generated current due to reflection, the disclosed nanoparticle layer can achieve the same or better performance compared with the PVD process. For example, as shown in Table 1, the nanoparticle approach can attain 2-8% loss of the short-circuit current I_{sc} as opposed to 8-10% loss for the PVD process. Note that the PV module's efficiency typically scales with I_{sc}. Thus, the nanoparticle layer disclosed herein displays as good as or better efficiency than the PVD-deposited optical filter layer.

In terms of power loss, filtering out the back-reflected blue light can cost 7-8% of the incident power. Hence for the grey and black tiles, this amounts to the total power loss. For colored tiles, scattering red light to provide a red hue can cost another 8-9% of power. Therefore, in total, a colored PV module or roof tile can lose up to approximately 20% of the incident solar power for hiding the PV cells and providing a colored appearance.

TABLE 1
Comparison of color match and efficiency.

| Coating | ΔE (Color Difference) | I_{sc} Loss |
|---|---|---|
| PVD BlackA | 4.19 | −8.16% |
| NP Fe₂O₃ | 3.84 | −3.96% |
| NP Fe₃O₄ | 2.99 | −3.19% |
| PVD Grey1 | 2.79 | −9.22% |
| NP ZnO | 3.77 | −8.84% |
| NP TiO₂ | 2.83 | −2.48% |

Regarding the cost advantage of nanoparticles, whereas typically the PVD process requires a vacuum chamber, the nanoparticle layer can be coated on glass with an in-air multi-nozzle-spray system. As a result, the disclosed system and methods can incur less capital expenditure.

In addition, the nanoparticle approach incurs lower operating expenses, because it involves less expensive materials than an optical color filter. For the PVD-based approach to depositing TCO as a color filter, one might need to use expensive In₂O₃-based material for a moisture barrier. By contrast, the primary material cost of depositing nanoparticles is the nanoparticle suspension, leading to a per-tile cost approximately 70% or less of that of the PVD-deposited TCO. With a recycling program to reuse the suspension, the cost of depositing nanoparticles can be further reduced to approximately 20% of the PVD per-tile cost, or less.

Table 2 shows the reliability of three different colors of nanoparticle-coated tiles, as measured by the “pull” or adhesion forces withstood by the samples in a pull test after temperature stress. As shown in the table, the PV roof tiles with nanoparticle layers can withstand a typical pull force of approximately 110 N. Thus, all the materials have passed the pull test, which requires a pull force of at least 90 N to be comparable to a standard solar module's encapsulant adhesion strength. Note that because the nanoparticles can dissolve within the encapsulant, they can withstand strong pull forces, so that there is no need of additional treatment to adhere the layers together. The nanoparticles' ability to dissolve into the encapsulant also helps protect them from the external environment.

TABLE 2
Reliability: Pull forces (N) in pull test
after temperature stress for three colors.

| Thin Coating | Thick Coating | Medium Coating |
|---|---|---|
| 114.4 | 109.6 | 115 |
| 127.2 | 120.5 | 94 |
| 136.6 | 130.2 | 109.8 |

In addition, neither nanoparticle coating material demonstrates current leakage under wet conditions. The tiles with nanoparticles have passed the current leakage test, which requires at least an initial resistance of 0.57 GΩ for a single 8.5″×13″ roof tile. Both black and grey nanoparticle materials displayed over 20 GΩ resistance. These strong current-leakage-prevention results can be attributed to the fact that the nanoparticles comprise non-conducting materials.

As will be discussed below, the deposition process for nanoparticle layers in PV modules or rooftop tiles can be readily implemented for high-volume manufacturing (HVM). Moreover, the manufacturing process has good scalability, and can be quickly put into place and automated. Another advantage of the highly stable materials used to deposit the nanoparticles is better process stability.

### Depositing a Layer of Nanoparticles in a PV Module

This section describes an exemplary process for depositing a layer of nanoparticles by spraying a nanoparticle suspension. Note that a number of different processes for nanoparticle deposition are possible, including those described in U.S. patent application Ser. No. 15/294,042, and are not limited by the present disclosure.

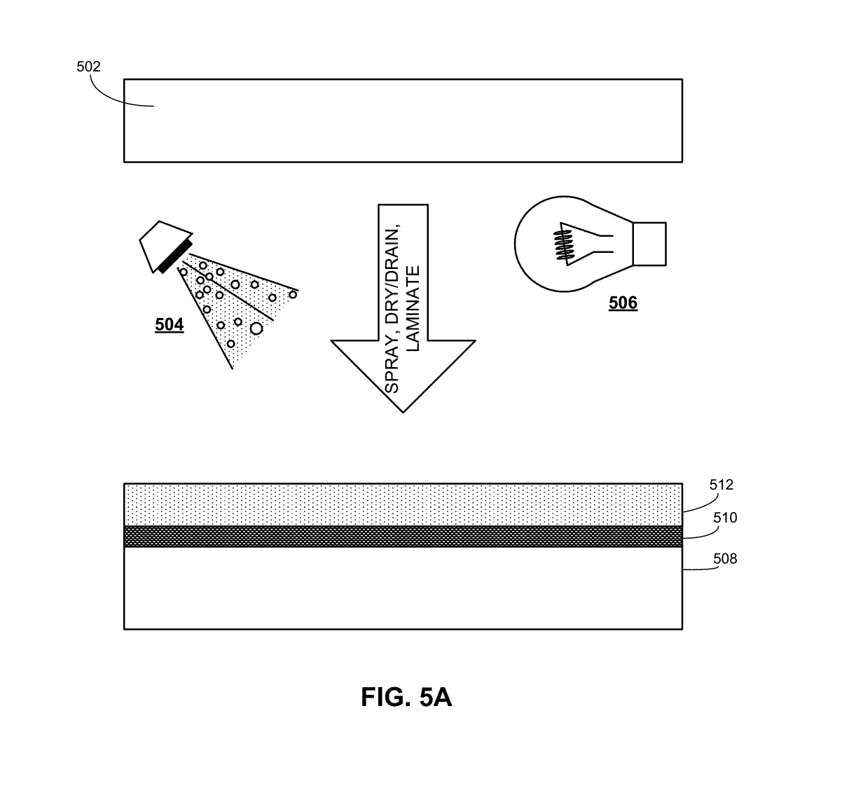

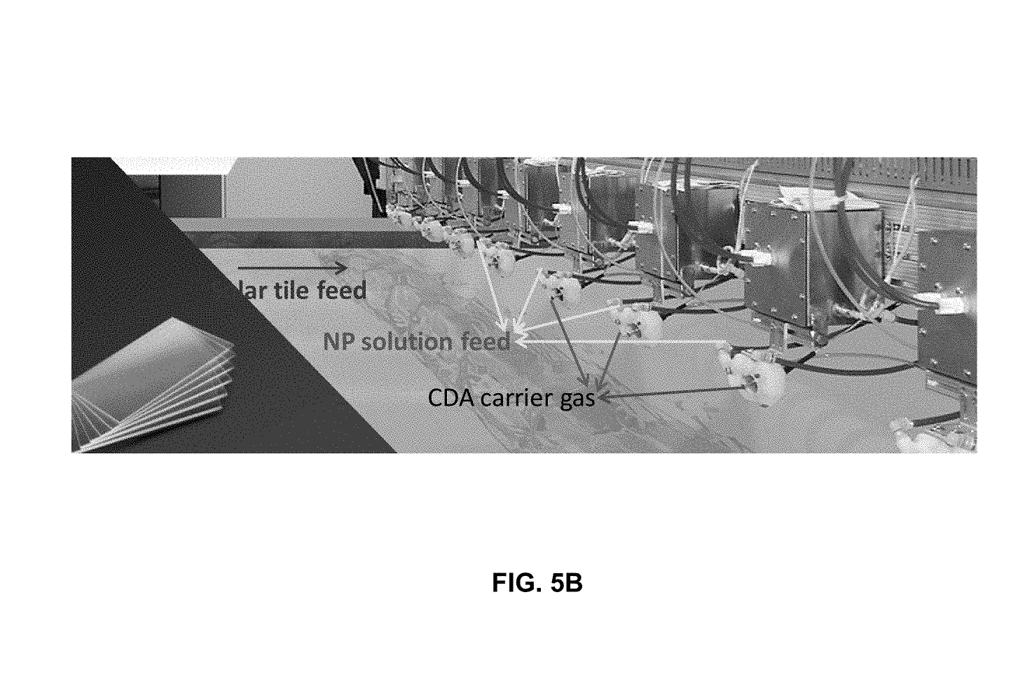

FIG. 5A illustrates coating of a glass cover sheet with a layer of nanoparticles, according to an embodiment. In this example, top glass cover 502 is placed with its inner surface facing towards a spray nozzle 504. The glass cover is then sprayed with a nanoparticle suspension or emulsion. In one embodiment, the nanoparticles are suspended in a medium, for example a mixture of water and isopropyl alcohol (IPA). The suspension can then be dried, e.g. using heater 506, leaving layer of nanoparticles 510 coated on the inner surface of top glass cover 508. In some embodiments, the medium can be drained after the spraying. Nanoparticle layer 510 can then be laminated with encapsulant layer 512. The lamination process can bond the nanoparticles to glass cover 508.

Note that, in this example, the PV module is shown upside-down, i.e., top glass cover 508 rests beneath nanoparticle layer 510, which in turn is beneath encapsulant 512. The PV module can be fabricated in such an inverted orientation to facilitate the deposition process, so that nanoparticle layer 510 can be sprayed onto glass 508, and subsequently laminated with encapsulant 512. It is also possible to spray the nanoparticle layer upward where the top glass cover has its inner surface facing downward.

FIG. 5B illustrates spray nozzles used to coat a glass cover sheet with a layer of nanoparticles, according to an embodiment. Multiple nozzles can be used, in order to provide superior production scalability. The spray nozzles can be integrated together with a chemical delivery system, belt and enclosure, in an integrated system. The nozzle and equipment needed to deposit nanoparticles can have a small size (e.g., approximately a cube with edges 6 to 7 feet), low capital and operating costs, and thus a small manufacturing process “footprint” overall.

In one embodiment, the spray nozzles can include one or more pressure nozzles. However, to prevent the nanoparticles from settling in the nanoparticle suspension, the deposition process may preferably include providing agitation to the suspension. In addition, the nanoparticle suspension may preferably be sprayed as a homogeneous mixture, rather than containing aggregated clusters or clumps of particles. This is particularly true when the nanoparticle size is small. An ultrasonic nozzle can be used, which employs ultrasonic wave energy to agitate and/or separate clusters or clumps into individual nanoparticles before or during the spraying process. A compressed-air carrier gas may also be used to improve nanoparticle uniformity.

The density and thickness of the deposited nanoparticle layer can affect the amount of light reflected to the viewer, and therefore the color brightness (or L* value) of the module's color appearance. Note that this also affects the module's efficiency, since light reflected by the nanoparticles cannot reach the PV cells to be converted to solar energy.

In an embodiment, the nanoparticles may be deposited with an area density of 0.5 mg/cm². The nanoparticles can be sprayed to form a layer with a nominal thickness of 100 nm to 1 μm. The nominal thickness can be calculated based on the density p of the nanoparticles and the mass M coated on top glass cover 508, for example as M/(A ρ), where A is the coated area and M/A is the deposited area density.

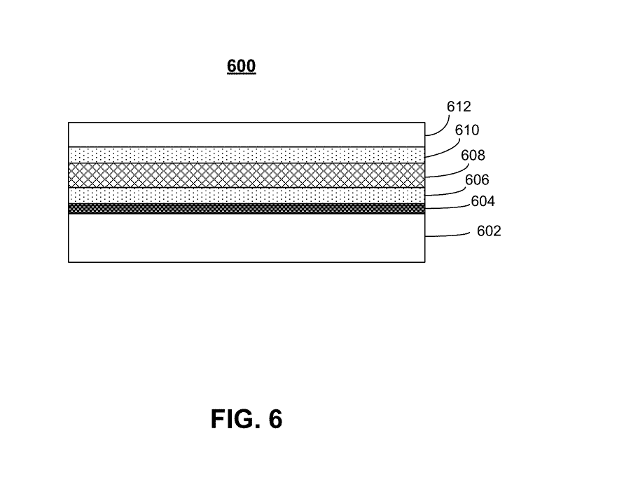

In one embodiment, the PV module or roof tile with a layer of nanoparticles can be fabricated in the opposite sequence from a conventional PV module, so as to facilitate spraying the nanoparticle suspension on the glass cover. FIG. 6 illustrates an exemplary as-fabricated photovoltaic module or roof tile containing a layer of nanoparticles, according to an embodiment. In this example, the PV module is positioned upside-down, relative to its standard orientation (i.e., relative to the orientation shown in FIGS. 3A and 3B). In particular, top glass cover 602 is on the bottom of the stack, as in the example of FIG. 5A.

Next, nanoparticle layer 604 is coated on the inner surface of glass cover 602, and laminated with encapsulant layer 606. In this example, glass cover 602, nanoparticle layer 604, and encapsulant layer 606 are adjacent to each other. Next, an array of PV cells 608 can be laid out on encapsulant layer 606. A bottom or second encapsulant layer 610 can be laminated on array of PV cells 608. Finally, a bottom or second glass cover 612 can be sealed on second encapsulant layer 610. Note that the nanoparticle coating will not fall off if turned to the standard orientation, i.e., the coating can adhere to the bottom of glass cover 602.

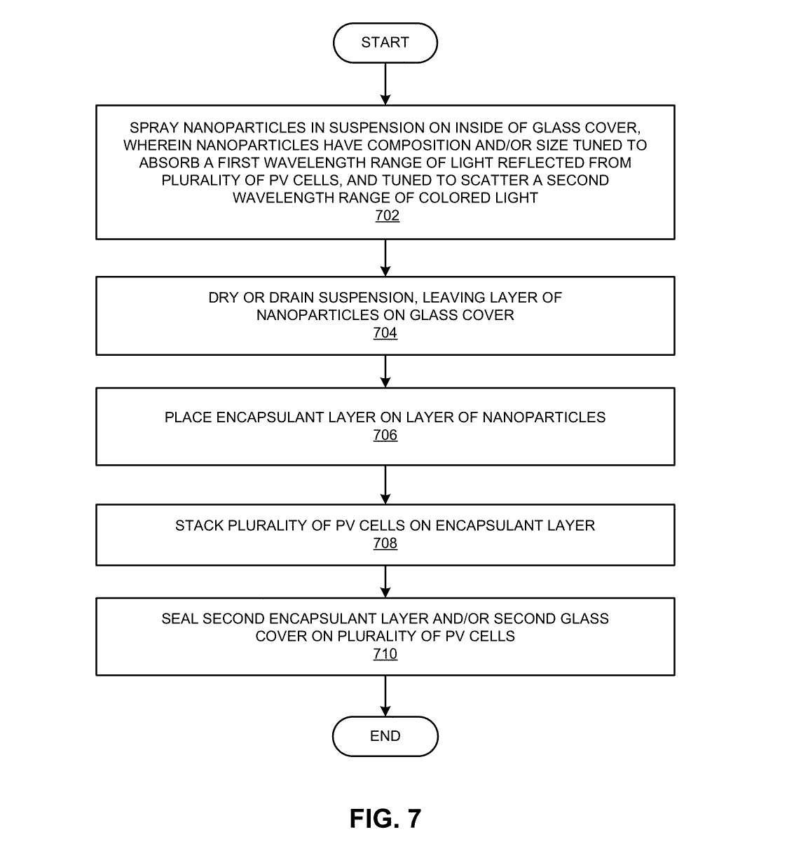

FIG. 7 shows a block diagram illustrating a process for depositing a layer of nanoparticles in a photovoltaic module or roof tile, according to an embodiment. First, a nanoparticle solution is sprayed on an inner surface of a glass cover (operation 702). The nanoparticles can have a composition and/or a size tuned to absorb a first wavelength range of light reflected from a plurality of PV cells, and tuned to scatter a second wavelength range of colored light. Depending on the material properties and the required coating color and thickness, the dispersion concentration can vary widely. In general, a lower concentration can reduce agglomeration and give better particle size control. The solution's nanoparticle concentration can have a lower range of 0.1% to 5%, by weight or volume. The solution's nanoparticle concentration can be as high as 20%. In one embodiment, the solution can contain 5% Fe₂O₃ and 1% TiO₂. The solution can comprise water, IPA, and 0.1% to 20% nanoparticles.

The solution is then dried or drained, leaving a layer of nanoparticles on the glass cover (operation 704). Next, an encapsulant layer is placed on the layer of nanoparticles (operation 706). In some embodiments, this lamination process is done with glue or a polymer material. A plurality of PV cells is then placed on the encapsulant layer (operation 708). Finally, a second encapsulant layer and/or a second glass cover is sealed on the plurality of PV cells (operation 710).

The foregoing descriptions of various embodiments have been presented only for purposes of illustration and description. They are not intended to be exhaustive or to limit the present system to the forms disclosed. Accordingly, many modifications and variations will be apparent to practitioners skilled in the art. Additionally, the above disclosure is not intended to limit the present system.

What is claimed is:

1. A photovoltaic module, comprising:
a front glass cover, wherein an inner surface of the front glass cover is coated with a layer of material that contains nanoparticles, which facilitates reflection of light of a predetermined color;
a back cover; and
at least one solar cell positioned between the front glass cover and the back cover.

2. The photovoltaic module of claim 1, wherein the nanoparticles comprise at least one of: ZnO, TiO₂, Fe₂O₃, and Fe₃O₄.

3. The photovoltaic module of claim 1, wherein a diameter of the nanoparticles has a range of 10-1000 nm.

4. The photovoltaic module of claim 1, wherein the nanoparticles are suspended in an encapsulant material.

5. The photovoltaic module of claim 4, wherein the encapsulant material comprises thermoplastic polyolefin (TPO) or ethylene-vinyl acetate (EVA).

6. The photovoltaic module of claim 1, wherein the nanoparticles comprise a ceramic.

7. The photovoltaic module of claim 1, wherein the layer of material contains two types of nanoparticles having different compositions and/or sizes.

8. The photovoltaic module of claim 1, wherein the nanoparticles are sprayed in a liquid or emulsion onto an inner surface of the glass cover.

9. The photovoltaic module of claim 8, wherein the liquid or emulsion comprises water, isopropyl alcohol (IPA), and 0.1% to 20% nanoparticles by weight or volume.

10. A method for manufacturing a photovoltaic module, the method comprising:
spraying a layer of liquid or emulsion that contains nanoparticles onto an inner surface of a front glass cover;
encapsulating at least one solar cell between the front glass cover and a back cover, wherein the nanoparticles are positioned between the front glass cover and the solar cell, thereby allowing the nanoparticles to reflect light of a predetermined color.

11. The method of claim 10, wherein the nanoparticles comprise at least one of: ZnO, TiO₂, Fe₂O₃, and Fe₃O₄.

12. The method of claim 10, wherein a diameter of the nanoparticles has a range of 10-1000 nm.

13. The method of claim 10, wherein the nanoparticles are suspended in an encapsulant material.

14. The method of claim 10, wherein the encapsulant material comprises thermoplastic polyolefin (TPO) or ethylene-vinyl acetate (EVA).

15. The method of claim 10, wherein the layer of material contains two types of nanoparticles having different compositions and/or sizes.

16. The method of claim 10, wherein the liquid or emulsion comprises water, isopropyl alcohol (IPA), and 0.1% to 20% nanoparticles by weight or volume.

17. A photovoltaic rooftop tile, comprising:
a front glass cover, wherein an inner surface of the front glass cover is coated with a layer of material that contains nanoparticles, which facilitates reflection of light of a predetermined color;
a back cover; and
at least one solar cell positioned between the front glass cover and the back cover.

18. The photovoltaic rooftop tile of claim 17, wherein the nanoparticles comprise at least one of: ZnO, TiO₂, Fe₂O₃, and Fe₃O₄

19. The photovoltaic rooftop tile of claim 17, wherein a diameter of the nanoparticles has a range of 10-1000 nm.

20. The photovoltaic rooftop tile of claim 17, wherein the nanoparticles are suspended in an encapsulant material.
